(19) United States
(12) Patent Application Publication
(10) Pub. No.: US 2007/0007242 A1
(43) Pub. Date: Jan. 11, 2007

(54) Method and system for producing crystalline thin films with a uniform crystalline orientation

(75) Inventor: James S. Im, New York, NY (US)

Correspondence Address: BAKER & BOTTS, 30 ROCKEFELLER PLAZA, 44TH FLOOR, NEW YORK, NY, 10112-4498, US

(73) Assignee: The Trustees Of Columbia University In The City Of New York

(21) Appl. No.: 11/373,771

(22) Filed: Mar. 10, 2006

Related U.S. Application Data
(63) Continuation of application No. PCT/US04/30329, filed on Sep. 16, 2004.
(60) Provisional application No. 60/503,419, filed on Sep. 16, 2003.

(51) Int. Cl. H01L 21/306; B44C 1/22; C23F 1/00

(52) U.S. Cl. 216/62; 216/66; 156/345.5

(57) ABSTRACT

System and method generating a polycrystalline thin film with a particular crystalline orientation for use as thin film transistors, microelectronic devices and the like. In one exemplary embodiment, a polycrystalline silicon thin film that has a substantially uniform crystalline orientation is produced so that its crystals are provided in at least one direction. The crystalline orientation may be any low index orientation and may be achieved with sequential lateral solidification. The polycrystalline thin film may then be crystallized in a direction that is perpendicular to the first direction by, e.g., a sequential lateral solidification procedure so that the crystalline orientation is approximately the same as the first direction, and is substantially uniform in all directions.

### FIELD OF THE INVENTION

The present invention relates to semiconductor processing techniques, and more particularly, techniques for producing semiconductors with a uniform crystalline orientation.

### BACKGROUND OF THE INVENTION

Semiconductor films, such as silicon films, are known to be used for providing pixels for liquid crystal display devices and organic light emitting diode display devices. To achieve high-speed response characteristics, it is preferable to produce high quality crystalline silicon semiconductors. Moreover, the performance of the Thin Film Transistors (“TFTs”) generally depends in part on the molecular structure of the semiconductor film. Factors such as interfacial structure, degree of molecular order and crystalline orientation of the thin film affects the properties of the TFT.

Certain control over the TFT microstructure may be obtained through the use of sequential lateral solidification (“SLS”) techniques. For example, in U.S. Pat. No. 6,322,625 (the “'625 patent”) issued to Im and U.S. patent application Ser. No. 09/390,535 (the “'535 application”), which is assigned to the common assignee of the present application, the entire disclosures of which are incorporated herein by reference, advantageous apparatus and methods for growing large grained polycrystalline or single crystal silicon structures using energy-controllable laser pulses and small-scale translation of a silicon sample to implement sequential lateral solidification have been described. As described in these patent documents, at least portions of the semiconductor film on a substrate are irradiated with a suitable radiation pulse to completely melt such portions of the film throughout their thickness. In this manner, when the molten semiconductor material solidifies, a crystalline structure grows into the solidifying portions from selected areas of the semiconductor film which did not undergo a complete melting. Thereafter, the beam pulses irradiate slightly offset from the crystallized areas so that the grain structure extends into the molten areas from the crystallized areas. With the sequential lateral solidification techniques, and the systems described therein, low defect density crystalline silicon films can be produced on those substrates that likely do not permit epitaxial regrowth, upon which high performance microelectronic devices can be fabricated.

For most polycrystalline materials, the crystallographic orientations of the individual grains are completely random. However, the electrical conductivity and other physical properties of a crystal depend on the crystallographic orientation. When a polycrystalline material is composed of grains with random orientations, the physical properties of the material depend on the average of all such orientations. Therefore, to obtain TFTs with predictable physical properties it is desirable to produce grains with uniform crystallographic orientations, e.g., in most if not all directions. To achieve a preferably optimum regularity between the grains, it may be preferable to form films where the uniform crystallographic orientation is any low index orientation. For example, when producing silicon thin films, a preferable orientation of the grains for an improved electrical conductivity or one of the other physical properties can be in the <100> direction, and may also be in the <110> direction and/or in the <111> direction. The resulting processed silicon thin film may have a surface that is approximately parallel to the face of the individual crystals and preferably uniform throughout.

### SUMMARY OF THE INVENTION

In accordance with the present invention, a method and system are provided for generating thin films with a particular crystalline orientation which can be uniform in all directions of the thin film. With certain conditions, a particular orientation can be formed naturally in the direction of lateral growth during a sequential lateral solidification process. For example, the {100} orientation of the crystallized thin film can be formed during the crystallization procedure following the irradiation for an initial scanning distance, and remains in a substantially the same orientation throughout the remainder of the scan or irradiation. The exemplary method and system of the present invention creates crystals in the thin film that are oriented in a particular direction to create a polycrystalline or single crystal thin film with a substantially uniform crystalline orientation.

In order to achieve these objectives as well as others that will become apparent with reference to the following specification, the method and system of the present invention are provided for processing an amorphous thin film sample into a polycrystalline (and possibly single crystal) thin film. In one exemplary embodiment of the present invention, the method and system generate a particular crystalline orientation in at least one section of the thin film sample. The thin film sample can be arranged in a first position with respect to a beam pulse such that at least one portion of the thin film is irradiated by the beam pulse so as to form at least one respective crystallized section of the thin film sample. The resulting crystallized section of the thin film sample may preferably have a substantially uniform crystalline orientation in the first direction. The thin film sample can then be arranged in a second position with respect to the beam pulse such that the second position of the thin film sample can be arranged approximately perpendicular to the first position of the thin film sample. After the thin film sample is arranged at the second position, the same section of the thin film sample can be irradiated by the beam pulse so as to provide a substantially uniform crystalline orientation in the second direction, with the second direction being approximately perpendicular to the first direction.

In another embodiment of the present invention, after the irradiation of the film sample in the first and second directions, the crystalline orientation of the thin film sample can become substantially uniform in all directions.

In yet another exemplary embodiment of the present invention, the polycrystalline thin film may be a silicon thin film. In addition, the preparation of a single crystal or polycrystalline thin film with a substantially uniform orientation may be accomplished by a sequential lateral solidification process, the uniform crystalline orientation may be any low index orientation, and can be provided in the {100} planes, {110} planes, and/or {111} planes.

For a better understanding of the present invention, together with other and further objects thereof, reference is made to the following description, taken in conjunction with the accompanying drawings, and its scope will be pointed out in the appending claims.

### BRIEF DESCRIPTION OF THE DRAWINGS

FIG. 1 shows a block diagram of a system for performing a preferred embodiment of a lateral solidification process on a sample according to the present invention;

FIG. 2 shows an enlarged cross-sectional side view of the sample which includes a semiconductor thin film;

FIG. 3 shows a top view of a mask according to the present invention which has a beam-blocking area surrounding one open or transparent area, and which can be used with the exemplary system of FIG. 1;

FIG. 4A shows an exemplary embodiment of the mask having a line pattern;

FIG. 4B shows an exemplary crystallized silicon film resulting from the use of the mask shown in FIG. 4A in the system of FIG. 1;

FIG. 5A shows an illustrative diagram showing irradiated areas of a silicon sample using a mask having a line pattern;

FIG. 5B shows areas of the sample irradiated using the mask of FIG. 4A after the initial irradiation of the sample and a translation thereof has occurred;

FIG. 5C shows an exemplary crystallized silicon film after a subsequent irradiation of the sample has occurred;

FIG. 5D shows an exemplary method of irradiating the silicon film at positions along the first direction;

FIG. 5E shows an exemplary method of irradiating the silicon film at alternating positions along the first direction;

FIG. 6 shows a resultant crystallized silicon thin film after the sample has been scanned/irradiated in a direction that is perpendicular to a first direction of irradiation;

FIG. 7 shows a flow diagram of a method according to the present invention in the system of FIG. 1.

Throughout the Figures, the same reference numerals and characters, unless otherwise stated, are used to denote like features, elements, components or portions of the illustrated embodiments. Moreover, while the present invention will now be described in detail with reference to the Figures, it is done so in connection with the illustrative embodiments.

### DETAILED DESCRIPTION OF THE PREFERRED EMBODIMENTS

Exemplary embodiments of the present invention provide techniques for producing polycrystalline thin film semiconductors with a uniform crystalline orientation in, e.g., all directions. In one exemplary embodiment, a uniform crystalline orientation can be obtained using the sequential lateral solidification process. Therefore, in order to fully understand the present invention, the sequential lateral solidification process is described further below.

As described in the '625 patent and the '535 application, the sequential lateral solidification (“SLS”) process is a technique for producing large grained silicon structures through small-scale unidirectional translation of a sample between sequential pulses emitted by an excimer laser. As each pulse is absorbed by the sample, a small area of the sample is caused to melt completely, and then resolidify laterally into a crystal region produced by the preceding pulses of a pulse set. It should be understood that various systems according to the present invention can be utilized to generate, nucleate, solidify and crystallize one or more areas on the semiconductor (e.g., silicon) film which have uniform material therein such that at least an active region of a thin-film transistor (“TFT”) can be placed in such areas. The exemplary embodiments of the systems and processes to generate such areas, as well as those of the resulting crystallized semiconductor thin films shall be described in further detail below. However, it should be understood that the present invention is in no way limited to the exemplary embodiments of the systems, processes and semiconductor thin films described herein.

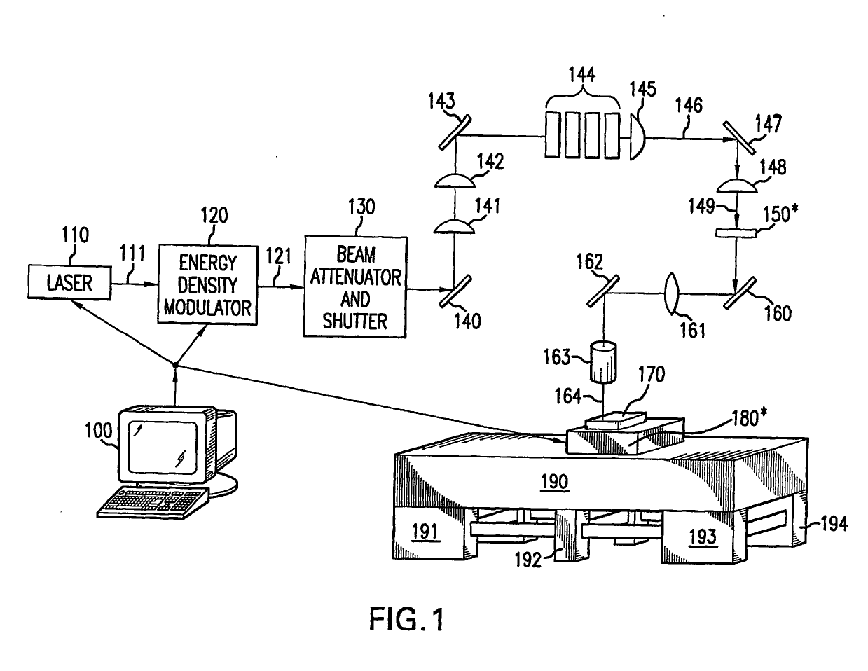

FIG. 1 shows a system that includes excimer laser 110, energy density modulator 120 to rapidly change the energy density of laser beam 111, beam attenuator and shutter 130, optics 140, 141, 142 and 143, beam homogenizer 144, lens system 145, 146, 148, a mask or masking system 150, lens system 161, 162, 163, incident laser pulse 164, thin silicon film sample 170, sample translation stage 180, granite block 190, support system 191, 192, 193, 194, 195, 196, and managing computer 100. As described in further detail in the '535 application, an amorphous silicon thin film sample 170 can be processed into a single or polycrystalline silicon thin film by generating a plurality of excimer laser pulses of a predetermined fluence, controllably modulating the fluence of the excimer laser pulses, homogenizing the modulated laser pulses in a predetermined plane, masking portions of the homogenized modulated laser pulses into patterned beamlets, irradiating an amorphous silicon thin film sample with the patterned beamlets to effect melting of portions thereof corresponding to the beamlets, and controllably translating the sample 170 with respect to the patterned beamlets and with respect to the controlled modulation to thereby process the amorphous silicon thin film sample into a single or polycrystalline silicon thin film. This is done by a sequential translation of the sample relative to the patterned beamlets and irradiation of the sample by patterned beamlets of varying fluence at corresponding sequential locations thereon.

The respective X and Y direction translation of the sample 170 may be affected by either the movement of the mask or masking system 150, and/or by the movement of the sample translation stage 180 under the direction of the computer 100. The sample translation stage 180 is preferably controlled by the computing arrangement 100 to effectuate the translations of the sample 170 in the planar X-Y directions, as well as in the Z direction. In this manner, the computing arrangement 100 controls the relative position of the sample 40 with respect to the irradiation beam pulse 164. The repetition and the energy density of the irradiation beam pulse 164 are also controlled by the computer 100. It should be understood by those skilled in the art that instead of the beam source 110 (e.g., the pulsed excimer laser), the irradiation beam pulse can be generated by another known source of short energy pulses suitable for completely melting throughout their entire thickness selected areas of the semiconductor (e.g., silicon) thin film of the sample 170 in the manner described herein below. Such known source can be a pulsed solid state laser, a chopped continuous wave laser, a pulsed electron beam, a pulsed ion beam, etc.

In the exemplary embodiment of the system shown in FIG. 1, the computing arrangement 100 according to the present invention controls translations of the sample 170 via the sample stage 180 for carrying out the processing of the semiconductor thin film of the sample 170. The computing arrangement 100 may also be adapted to control the translations of the mask 150 and/or the beam source 110 mounted in an appropriate mask/laser beam translation stage (not shown for the simplicity of the depiction) to translate or shift the intensity pattern of the irradiation beam pulses 164, with respect to the semiconductor thin film of the sample 170, along a controlled beam path. Another possible way to translate or shift the intensity pattern of the irradiation beam pulse is for the computer 100 to control a beam steering mirror of the system of FIG. 1. The exemplary system of FIG. 1 may be used to carry out the processing of the silicon thin film of the sample 170 in the manner described below in further detail.

For example, the mask or masking system 150 can be used by the exemplary system of the present invention to define the profile of the resulting masked beam pulse 164 to melt and then crystallize certain portions of the sample 170. The following embodiments of the present invention will now be described with reference to the foregoing processing technique.

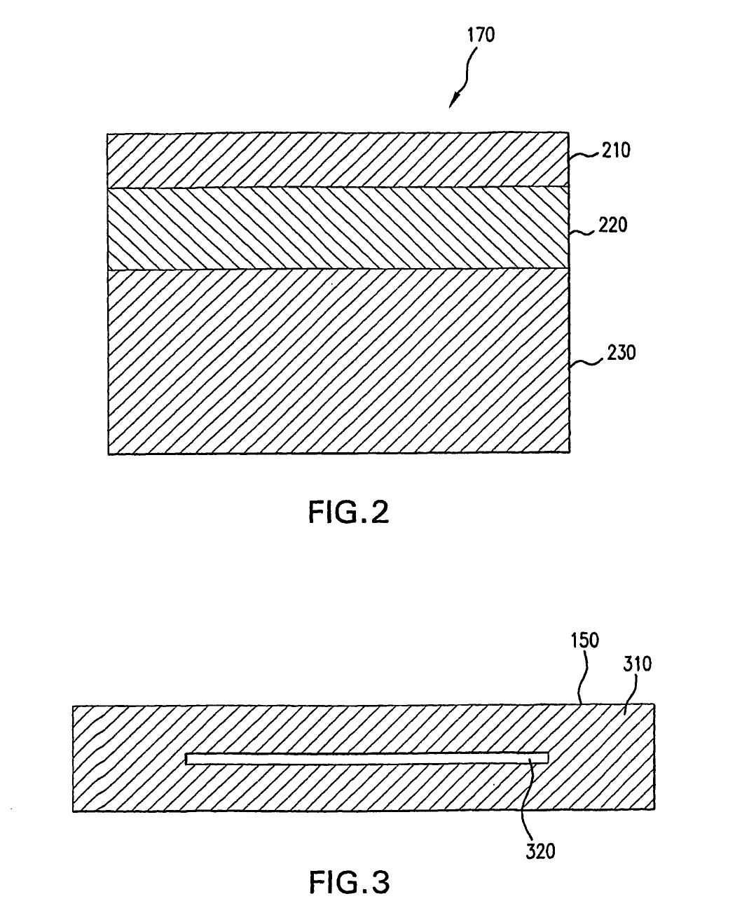

As illustrated in FIG. 2, the semiconductor thin film 210 of the sample 170 can be directly situated on, for example, a glass substrate 230 and may be provided on one or more intermediate layers 220 there between. The semiconductor thin film 210 can have a thickness between 100 Å and 10,000 Å (1 μm) so long as at least certain necessary areas thereof can be at least partially or preferably completely melted throughout their entire thickness. According to an exemplary embodiment of the present invention, the semiconductor thin film 210 can be composed of silicon, germanium, silicon germanium (SiGe), all of which preferably have low levels of impurities. It is also possible to utilize other elements or semiconductor materials for the semiconductor thin film 210. The intermediary layer 220, which is situated immediately underneath the semiconductor thin film 210, can be composed of silicon oxide (SiO₂), (silicon nitride (Si₃N₄), and/or mixtures of oxide, nitride or other materials that are suitable for promoting nucleation and small grain growth within the designated areas of the semiconductor thin film 210 of the sample 170. The temperature of the glass substrate 230 can be between room temperature and 800° C. Higher temperatures of the glass substrate 230 can be accomplished by preheating the substrate 230 which would effectively allow larger grains to be grown in the nucleated, re-solidified, and then crystallized areas of the semiconductor thin film 210 of the sample 170 due to the proximity of the glass substrate 230 to the thin film 210.

The semiconductor thin film 210 can be irradiated by the beam pulse 164 which is patterned using the mask 150 according to a first exemplary embodiment of the present invention as shown in FIG. 3. The first exemplary mask 150 is sized such that its cross-sectional area is larger than that of the cross-sectional area of the beam pulse 164. In this manner, the mask 150 can pattern the pulsed beam to have a shape and profile directed by open or transparent regions of the mask 150. In this exemplary embodiment, the mask 150 includes a beam-blocking section 310 and an open or transparent section 320. The beam-blocking section 310 prevents those areas of the pulsed beam impinging such section 310 from being irradiated there-through, thus preventing the beam from being further forwarded to the optics of the exemplary system of the present invention shown in FIG. 1 so as to irradiate the corresponding areas of the semiconductor thin film 210 provided on the sample 170. In contrast, the exemplary open or transparent section 320 has a slit shape that allows the portion of the beam pulse 164. whose cross-section corresponds to that of the section 320 to be shaped in substantially the same manner, to enter the optics of the system according to the present invention, and irradiate the corresponding areas of the semiconductor thin film 210. In this manner, the mask 150 is capable of patterning the beam pulse 164 so as to impinge the semiconductor thin film 210 of the sample 170 at predetermined portions thereof based on the dimension and shape of the mask 150 as shall be described in further detail below.

In accordance with the present invention, a method of generating a particular crystalline orientation in at least one section of a thin film which can be executed by the system of FIG. 1 is described. To summarize such exemplary method, arrange the sample 170 in one position, and irradiate a portion of the sample in a particular direction so as to form a polycrystalline section that has a substantially uniform crystalline orientation in this particular direction.

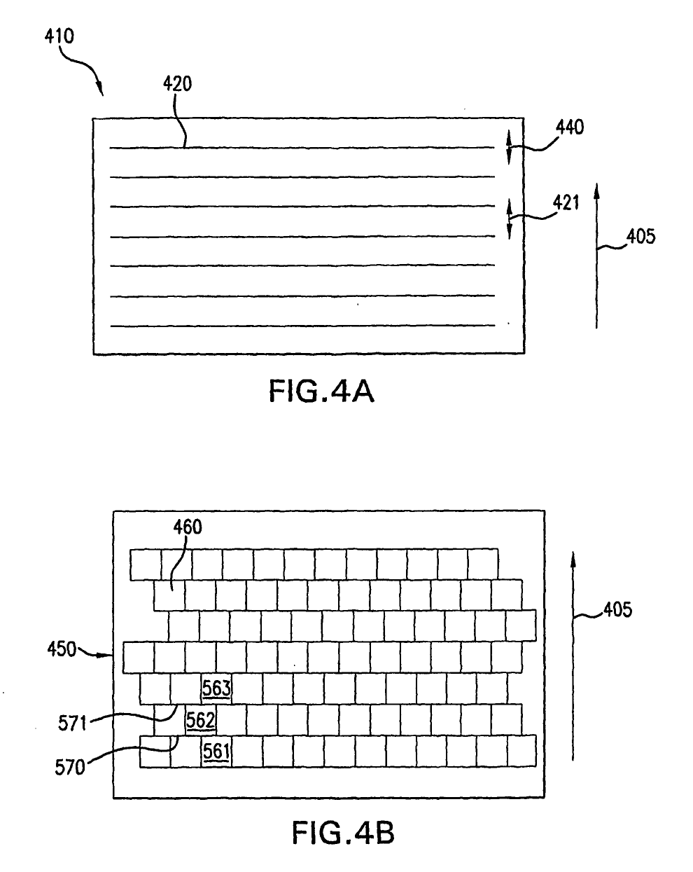

In a preferred embodiment of the present invention, the sample 170 may be translated in the first direction 405 (e.g., the Y direction) with respect to the impingement of the laser pulses 164 on the sample 170, either by movement of masking system 150 or sample translation stage 180, using an exemplary mask having a pattern of lines as shown in FIG. 4A. Each line or slit 420 should extend across on the mask 170 so as to shape the homogenized laser beam 111 incident on the mask. Each slit of the mask 150 should have a width 440 that is sufficiently narrow to prevent any nucleation from taking place in the irradiated region of sample 170. The width 440 of each slit 420 generally depends on a number of factors, including the energy density of the incident laser pulse, the duration of the incident laser pulse, the thickness of the silicon thin film sample, and the temperature and conductivity of the silicon substrate. For example, the line should preferably not be more than 2 micrometers wide when a 500 Angstrom film is to be irradiated at room temperature with a laser pulse of 30 ns and having an energy density that slightly exceeds the complete melt threshold of the sample 170.

In operation, when the sample 170 is translated in the first direction 405 (e.g., the Y direction) and the mask 410 of FIG. 4A is used in the masking system 150, a processed sample 450 having crystallized regions 460 can be produced, as shown in FIG. 4B. Each crystal region 460, obtained with directional solidification, consists of a long grained, directionally controlled crystal. Depending on the periodicity 421 of the masking slits 420 (e.g., the distance between the slits 420) on the mask 410, the length of the grains will be longer or shorter according to the SLS procedures and systems described in the '535 application and '625 patent, as well as shall be provided below. In a preferred embodiment of the present invention, the mask 410 can produce a large set of relatively short crystals with a particular orientation in the direction of the lateral growth of the grains (i.e., in the scan direction). In order to prevent silicon regions that do not have the particular orientation (e.g. amorphous silicon or grains that grew during the early part of the scan that are smaller and do not have a controlled orientation) from being left on the sample 170, the Y translation distance should be preferably at least as long as the distance 421 between the mask lines. For example, the translation of the sample 170 or the mask 150 should be at least one micron greater than this distance 421 to eliminate small crystals that inevitably form at the initial stage of a directionally controlled polycrystalline structure.

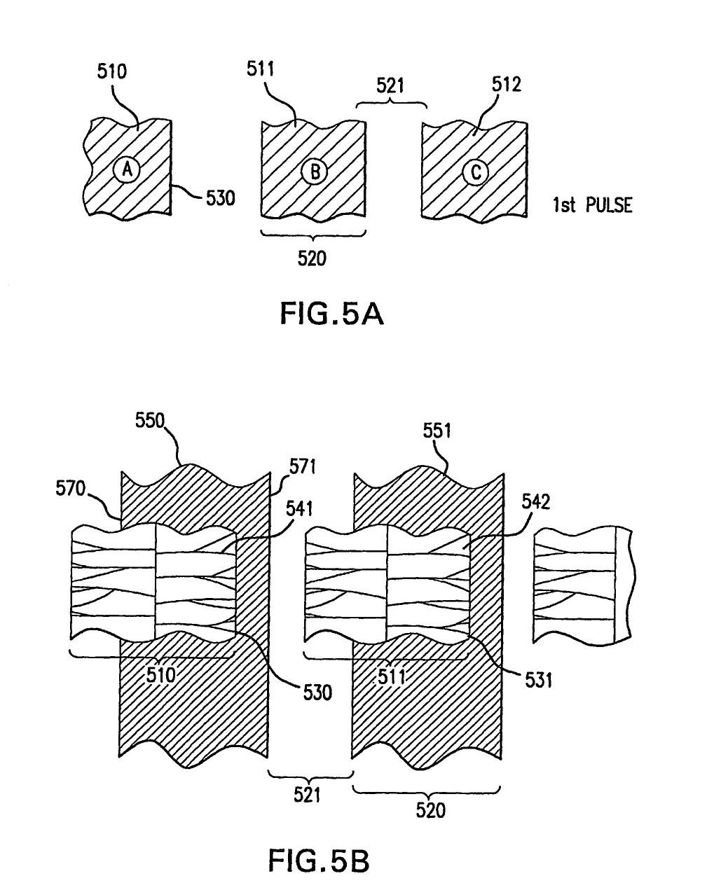

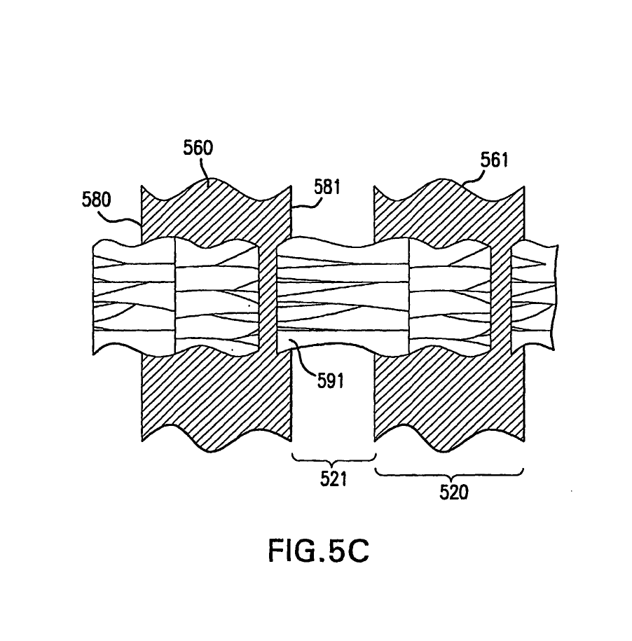

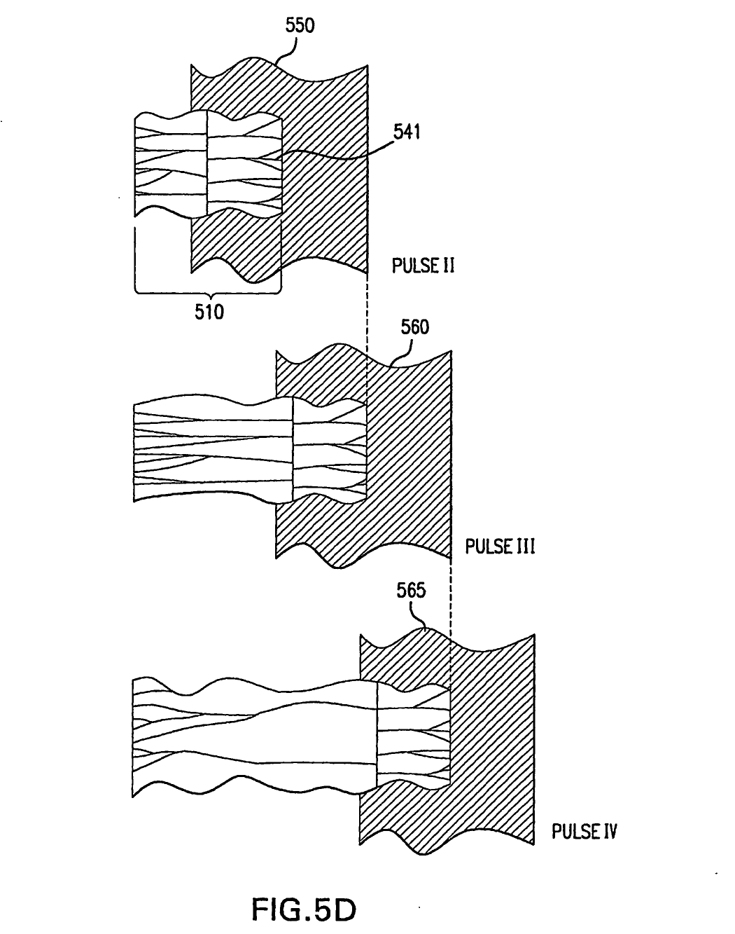

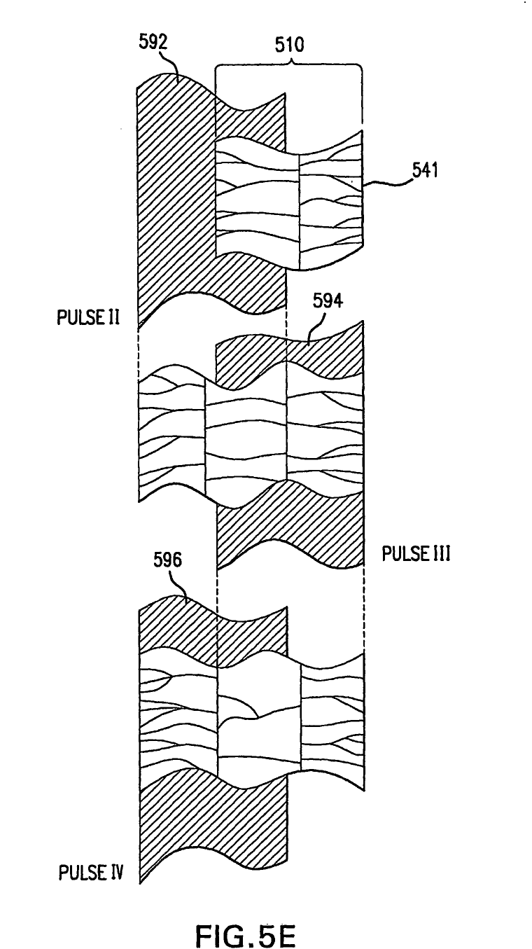

As shown in FIG. 5A, the laser pulse can melt regions 510, 511, 512 on the sample, where each melt region 520 may be approximately 4 micrometers wide, and can be spaced a distance 521 which is, e.g., the distance 421, that may be approximately 2 micrometers. This first laser pulse would induce the growth of crystals in the irradiated regions 510, 511, 512, starting from the melt boundaries 530 and proceeding into the melt region so that the polycrystalline silicon forms in the irradiated regions.

In an exemplary embodiment, in order to eliminate the numerous small initial crystals 541, 542, which may have random crystalline orientations and form at the melt boundaries 530, 531 the sample 170 may be irradiated by a second pulse, according to the SLS procedures and systems used as described in the '535 application and the '625 patent. The second irradiation may be in the first direction 405 (e.g., the Y direction) with respect to the impingement of the laser pulse 164 on the sample 170, and occur at a second position on the sample, preferably at a distance less than the lateral growth distance of the previous irradiation, either by movement of masking system 150 or sample translation stage 180. As shown in FIG. 5B, the second laser pulse can melt regions 550 and 551, on the sample, where each melt region 520 may be approximately 4 micrometers wide, and can be spaced a distance 521, that may be approximately 2 micrometers, e.g., the distance 421. The second laser pulse will induce the growth of crystals in the irradiated regions 550, 551, starting from the melt boundaries 570, 571, including a portion of the crystals in the previously irradiated regions 510, 511, and proceeding into the melt region so that the polycrystalline silicon forms in the irradiated regions 550, 551. In a preferred embodiment the second irradiation may use an exemplary mask having a pattern of lines as shown in FIG. 4A. The length of the grains can be defined by the boundaries of the crystallized regions 570, 571, and may be longer or shorter according to the SLS procedures and systems used as described in the '535 application and the '625 patent.

In a further exemplary embodiment, to eliminate the small initial crystals 590, which may have random crystalline orientations and form at the melt boundaries 591, the sample 170 may be irradiated by a third pulse, according to the SLS procedures and systems used as described in the '535 application and the '625 patent. The third irradiation may be in the first direction 405 (e.g., the Y direction) with respect to the impingement of the laser pulse 164 on the sample 170, and occur at a third position on the sample 170, preferably at a distance less than the lateral growth distance of the previous irradiation, either by movement of masking system 150 or sample translation stage 180. As shown in FIG. 5B, the third laser pulse can melt regions 560 and 561, on the sample, where each melt region 520 may be approximately 4 micrometers wide, and can be spaced a distance 521, that may be approximately 2 micrometers, e.g., the distance 421. The third laser pulse will induce the growth of crystals in the irradiated regions 560, 561, starting from the melt boundaries 580, 581, including a portion of the crystals in the previously irradiated regions 550, 551, and proceeding into the melt region so that the polycrystalline silicon forms in the irradiated regions. In a preferred embodiment the third irradiation may use an exemplary mask having a pattern of lines as shown in FIG. 4A. In a preferred embodiment of the invention, irradiation of the sample at positions along the first direction 405 (e.g., the Y direction) according to the SLS procedures and systems used as described in the '535 application and the '625 patent may be repeated 550, 560, 565 until the numerous small initial crystals 541, which may have random crystalline orientations and form at the melt boundaries 530, are eliminated across the entire sample as shown in FIG. 5D.

In another preferred embodiment of the invention, irradiation of the sample at positions along the first direction 405 (e.g., the Y direction), according to the SLS procedures and systems used as described in the '535 application and the '625 patent, may be repeated at positions 592, 594, 596 that alternate from one side with respect to the first irradiation position 510 to the other side with respect to the first irradiation position until the numerous small initial crystals 541, which may have random crystalline orientations and form at the melt boundaries 530, are eliminated across the entire sample as shown in FIG. 5E.

In a further preferred embodiment of the present invention, the resulting crystalline orientation across the entire sample in the first irradiated direction may be any low index crystalline orientation (for example, naturally formed low index orientations). In still a further preferred embodiment the resulting uniform crystalline orientation in the first irradiated direction may be the {100} plane, the {110} plane, and/or the {111} plane.

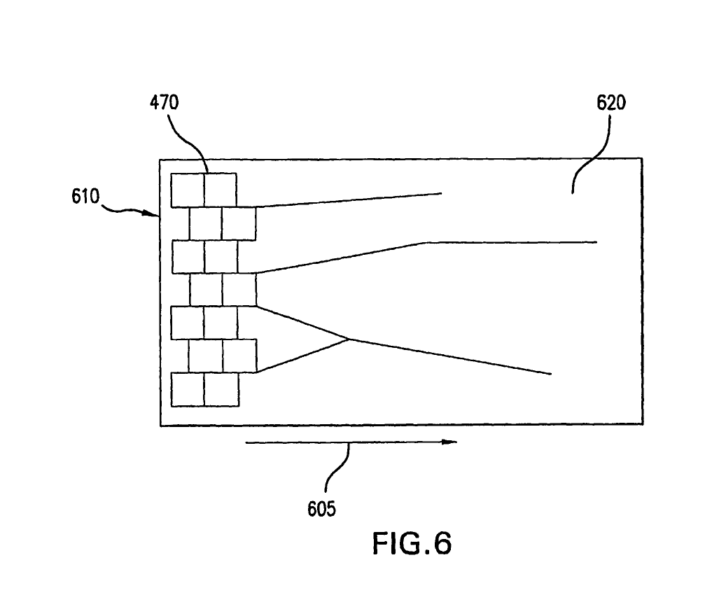

In the second stage of the preferred embodiment of the present invention, the thin film sample 450 can be arranged into a second position that is perpendicular to the first position. This can be done by rotating the sample 170, 450 by approximately 90° after the initial processing of the sample 170, 450 is completed. The sample 450 can then be irradiated in a direction (e.g., the X direction), which is perpendicular to the first direction, as shown in FIG. 6. In particular, the sample 450 is translated in a second direction 605 (which is perpendicular to the first direction 405 with respect to the laser pulse 164), either by movement of the mask or masking system 150 and/or the sample 170, 450 of the sample translation stage 180, using the mask 150 having a single slit pattern as shown in FIG. 3. When the sample 450 is translated in the second direction 605 and the mask 350 of FIG. 3 is used in the masking system 150, a film region 620 may be produced, as shown in FIG. 6.

In another embodiment of the present invention, the sample 450 can be translated in a second direction perpendicular to the first direction 605 with respect to the laser pulse 164, either by movement of masking system 150 or sample translation stage 180, using a mask having a pattern of multiple slits 420 as shown in FIG. 4A. Preferably, the same mask is used in the first and second stages described above. The resulting crystallized region 620 may preferably consist of long grained, directionally controlled crystals with a preferred orientation of the crystal in the direction of lateral growth of the grains (i.e., in the scanned X direction). In a preferred embodiment, the uniform crystalline orientation obtained in the first direction is retained after irradiation in the second direction. Since the sample 450, 610 (after the first scan processing/state) may have a uniform crystalline orientation, irradiating the sample 450 in the second direction 605 may result in a directionally processed sample 610 having grains crystallized in a preferably crystallographic orientation in both perpendicular directions of the crystal. The resulting thin film sample 610, will likely result in a textured film with a preferred crystallographic orientation in all directions.

In a preferred embodiment of the present invention, the resulting crystalline orientation in the second scan direction will be approximately the same as that in the first scan direction, and may be any low index orientation. In further embodiment the crystalline orientation will be the [100] plane, the [110] plane and/or the [111] plane. As a result, the crystalline orientation in at least one section of the sample 450, 610 (and preferably in most or all sections thereof) will have a substantially uniform crystalline orientation in all three orthogonal directions.

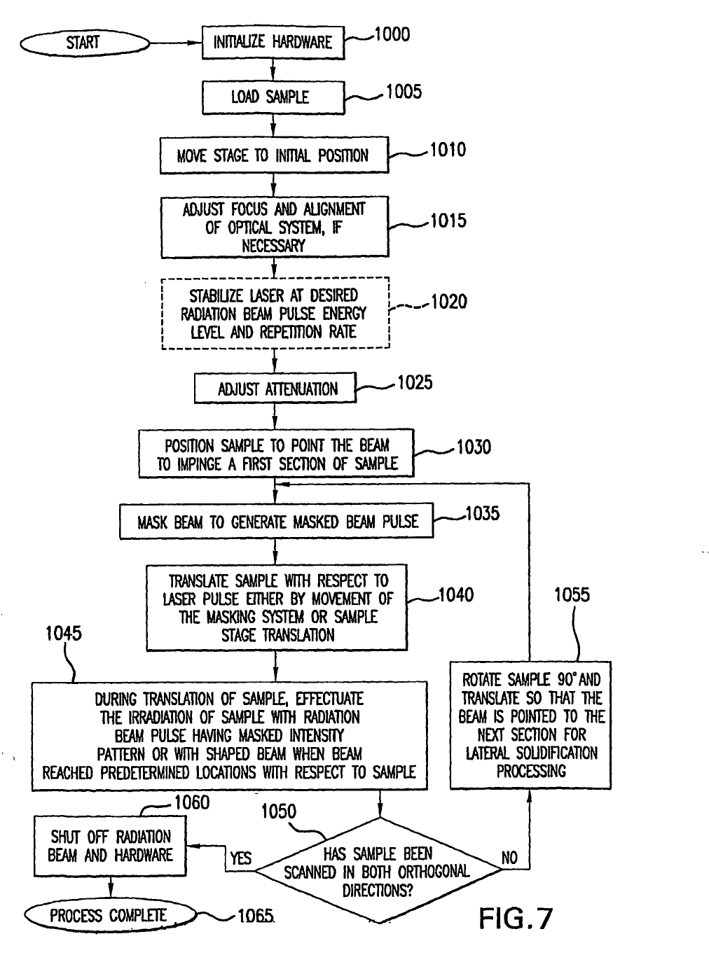

Referring to FIG. 7, exemplary procedures executed by the computer 100 of FIG. 1 to achieve the above-described orientation in the crystals of the sample are described below. In particular, the various electronics of the system shown in FIG. 1 are initialized 1000 by the computer to initiate the process. The thin silicon film sample 170 is then loaded onto the sample translation stage 1005. It should be noted that such loading may be either manual or robotically implemented under the control of computer 100.

Next, the sample translation stage is moved into an initial position 1010, which may include an alignment with respect to reference features on the sample. The various optical components of the system are focused 1015 if necessary. The laser is then stabilized 1020 to a desired energy level and repetition rate, as needed to fully melt the silicon sample in accordance with the particular processing to be carried out. If necessary, the attenuation of the laser pulses is finely adjusted 1025.

Next, the sample 170 is positioned to direct the beam so as to impinge the first section of sample 1030. The beam is masked with the appropriate mask pattern 1035. The sample 170 is translated in the X or Y directions 1040 in an amount less than the super lateral grown distance. During the translation, the shutter is opened 1045 to expose the sample to a single pulse of irradiation and accordingly, to commence the sequential lateral solidification process. It is then determined if the sample 170 has been irradiated in both orthogonal directions 1050. If that is not the case, the sample 170 is rotated 90° and translated so that the beam is directed to the next section for performing the sequential lateral solidification procedure 1055 in the second direction. The beam is again masked with the appropriate mask pattern 1035, and the sample 170 is again translated in the X or Y directions 1040, with the shutter opened 1045 to expose the sample to a single pulse of irradiation. When both orthogonal directions of the sample 170 have been scanned thus preferably forming a low index orientation of the crystals in the entire same (or portions thereof), the laser hardware is shut off 1060, and the process is completed 1065. Of course, if processing of additional samples is desired or if the present invention is utilized for batch processing, steps 1005-1055 can be repeated on each sample.

The foregoing merely illustrates the principles of the invention. Various modifications and alterations to the described embodiments will be apparent to those skilled in the art in view of the teachings herein. For example, while the above embodiment has been described with respect to at least partial lateral solidification and crystallization of the semiconductor thin film, it may apply to other materials processing techniques, such as micro-machining, and micro-patterning techniques, including those described in International patent application no. PCT/US01/12799 and U.S. patent application Ser. Nos. 09/390,535, 09/390,537 and 09/526,585, the entire disclosures of which are incorporated herein by reference. The various mask patterns and intensity beam patterns described in the above-referenced patent application can also be utilized with the process and system of the present invention. It will thus be appreciated that those skilled in the art will be able to devise numerous systems and methods which, although not explicitly shown or described herein, embody the principles of the invention and are thus within the spirit and scope of the present invention.

1. A method of generating a particular crystalline orientation in at least one section of a thin film sample, comprising the steps of:
(a) arranging the thin film sample in a first position;
(b) irradiating at least one portion of the at least one section of the thin film sample to form at least one polycrystalline section of the thin film sample, the at least one polycrystalline section having an approximately uniform crystalline orientation in a first direction;
(c) arranging the thin film sample to be in a second position with respect to the at least one beam pulse, the second position being approximately perpendicular relative to the first position; and
(d) irradiating the at least one polycrystalline section of the thin film sample arranged in the second position so as to provide an approximately uniform crystalline orientation in a second direction, the second direction being approximately perpendicular relative to the first direction, wherein the at least one polycrystalline section of the thin film sample has an approximately uniform crystalline orientation in both the first direction and the second direction.

2. The method according to claim 1, wherein, after step (b) further comprising the step of irradiating the thin film sample at positions along the first direction until the thin film sample is irradiated across the entire sample.

3. The method according to claim 1, wherein, after step (b) further comprising the step of irradiating the thin film sample at positions along the first direction alternating from side to side with respect to the first irradiation position until the thin film sample is irradiated across the entire sample.

4. The method according to claim 2 or 3, wherein the pulses impinge the thin film sample at a distance greater than the lateral growth distance of the previous irradiation.

5. The method according to claim 1, wherein, after step (d), the crystalline orientation of the thin film sample is uniform in all directions.

6. The method of claim 1, wherein the thin film sample is a silicon thin film.

7. The method of claim 1, wherein the thin film sample is a metal thin film sample.

8. The method of claim 1, wherein the thin film sample is an aluminum thin film sample.

9. The method of claim 1, wherein steps (b) and (d) are performed using a sequential lateral solidification process.

10. The method of claim 1, wherein the uniform crystalline orientation is an arbitrary low index orientation.

11. The method of claim 1, wherein the uniform crystalline orientation is the {100} plane.

12. The method of claim 1, wherein the uniform crystalline orientation is the {110} plane.

13. The method of claim 1, wherein the uniform crystalline orientation is the {111} plane.

14. A system for generating a particular crystalline orientation in at least one section of a thin film sample, comprising:
a logic arrangement which is operable to:
(a) irradiate at least one portion of the at least one section of the thin film sample when the thin film sample is arranged in a first position so as to form at least one polycrystalline section of the thin film sample, the at least one polycrystalline section having a substantially uniform crystalline orientation in a first direction,
(b) arrange the thin film sample to be in a second position with respect to the at least one beam pulse, the second position being approximately perpendicular relative to the first position, and
(c) irradiate the at least one polycrystalline section of the thin film sample, when the thin film sample is arranged in the second position, so as to provide an approximately uniform crystalline orientation to be in a second direction, the second direction being perpendicular to first direction, wherein the at least one polycrystalline section of the thin film sample has an approximately uniform crystalline orientation in both the first direction and the second direction.

15. The system of claim 14, wherein, after step (a) further comprising the step of irradiating the thin film sample at positions along the first direction until the thin film sample is irradiated across the entire sample.

16. The system of claim 14, wherein, after step (a) further comprising the step of irradiating the thin film sample at positions along the first direction alternating from side to side with respect to the first irradiation position until the thin film sample is irradiated across the entire sample.

17. The system of claim 15 or 16, wherein the pulses impinge the thin film sample at a distance less than the lateral growth distance of the previous irradiation.

18. The system of claim 14, wherein, after step (c), the crystalline orientation of the thin film sample is uniform in all directions.

19. The system of claim 14, wherein the thin film sample is a silicon thin film.

20. The system of claim 14, wherein steps (a) and (c) are performed using a sequential lateral solidification process.
